(19) United States
(12) Patent Application Publication
(10) Pub. No.: US 2025/0273005 A1
(43) Pub. Date: Aug. 28, 2025

(54) FINGERPRINT SENSOR PACKAGES AND DEVICES INCLUDING THE SAME

(71) Applicant: Samsung Electronics Co., Ltd., Suwon-si (KR)

(72) Inventors: HOON JEONG, Suwon-si (KR); YE CHENG CHENG, Suwon-si (KR)

(21) Appl. No.: 18/922,517

(22) Filed: Oct. 22, 2024

(30) Foreign Application Priority Data
Feb. 23, 2024 (KR) 10-2024-0026518

(51) Int. Cl. G06V 40/13; H01L 21/56; H01L 23/00; H01L 23/31

(52) U.S. Cl. CPC G06V 40/1306; G06V 40/1329; H01L 21/565; H01L 23/3121; H01L 24/05; H01L 24/48; H01L 2224/04105; H01L 2224/05553; H01L 2224/48227; H01L 2924/19041

(57) ABSTRACT

A fingerprint sensor package, comprising: a package substrate, wherein an upper surface of the package substrate includes a sensing region and a peripheral region that extends around the sensing region, and wherein a lower surface of the package substrate includes a mounting region and a connection region that extends around the mounting region; external connection pads in the connection region on the lower surface of the package substrate; a lower protection layer on the lower surface of the package substrate, wherein the lower protection layer includes openings that overlap at least a portion of the external connection pads respectively, wherein the lower protection layer includes a protection layer pattern that overlaps the external connection pads in the openings; and an anisotropic conductive layer on the external connection pads in the openings and on the lower protection layer.

### CROSS-REFERENCE TO RELATED APPLICATIONS

This application claims priority benefit of under 35 U.S.C. § 119 to Korean Patent Application No. 10-2024-0026518, filed on Feb. 23, 2024 in the Korean Intellectual Property Office (KIPO), the disclosures of which are herein incorporated by reference in their entirety.

### BACKGROUND OF THE INVENTION

### 1. Field of the Invention

Example embodiments of the present inventive concepts relate to fingerprint sensors. More particularly, example embodiments of the present inventive concepts relate to capacitive fingerprint sensor packages and devices (e.g., smart cards) including the same.

### 2. Description of the Related Art

In order to prevent loss and theft of (payment) devices (e.g., credit cards), the demand for (payment) devices (e.g., credit cards) with a fingerprint authentication function is increasing. In order to manufacture a (payment) device (e.g., a credit card) with the fingerprint authentication function, a fingerprint sensor package capable of fingerprint recognition may be mounted on the device. For example, a payment device (e.g., a credit card), including a sensor (e.g., a fingerprint sensor package) with an authentication function (e.g., a fingerprint authentication function) may be referred to as a smart card. An anisotropic conductive film (ACF) may be used to mount the fingerprint sensor package on the smart card. When a force is applied to compress the anisotropic conductive film, there may be a problem in that the anisotropic conductive film escapes from a region in which a connection pad is disposed by pressure and then contacts a redistribution wiring or a ground pattern located on an upper surface of the fingerprint sensor package, thereby causing a short circuit.

### SUMMARY OF THE INVENTION

Example embodiments may provide a fingerprint sensor package capable of preventing a short circuit due to escape of an anisotropic conductive layer.

Example embodiments may provide a smart card including the fingerprint sensor package.

In accordance with example embodiments, a fingerprint sensor package, comprising: a package substrate including an upper surface and a lower surface that is opposite to the upper surface in a first direction, wherein the first direction is perpendicular to the upper surface of the package substrate, wherein the upper surface of the package substrate includes a sensing region and a peripheral region that extends around the sensing region, and wherein the lower surface of the package substrate includes a mounting region and a connection region that extends around the mounting region; external connection pads in the connection region on the lower surface of the package substrate; a plurality of capacitor patterns in the sensing region on the upper surface of the package substrate; a control portion in the mounting region on the lower surface of the package substrate, wherein the control portion includes a sensor chip and a passive element that is adjacent the sensor chip; a lower protection layer on the lower surface of the package substrate, wherein the lower protection layer includes openings that overlap at least a portion of the external connection pads in the first direction respectively, wherein the lower protection layer includes a protection layer pattern that overlaps the external connection pads in the first direction in the openings; and an anisotropic conductive layer on the external connection pads in the openings and on the lower protection layer.

In accordance with example embodiments, a fingerprint sensor package, comprising: a package substrate including: a first substrate having a sensing region and an adhesion region extending around the sensing region on an upper surface thereof and having first bonding pads on a lower surface thereof; and a second substrate having second bonding pads and external connection pads on a lower surface thereof, the second bonding pads being electrically connected to the first bonding pads through conductive wires, the second substrate having an opening region that overlaps the sensing region of the upper surface of the first substrate in a first direction, the second substrate being adhered on the adhesion region of the upper surface of the first substrate; a plurality of capacitor patterns in the sensing region on the upper surface of the first substrate; a control portion on the lower surface of the first substrate, the control portion including a sensor chip and a passive element adjacent the sensor chip; a lower protection layer on the lower surface of the second substrate and having openings that overlap the external connection pads in the first direction respectively, the lower protection layer having a protection layer pattern that overlaps a portion of the external connection pads in the openings in the first direction; and an anisotropic conductive layer on the external connection pads in the openings and on the lower protection layer, wherein the first direction is perpendicular to the upper surface of the first substrate.

In accordance with example embodiments, a fingerprint sensor package, comprising: a package substrate including an upper surface and a lower surface that is opposite to the upper surface in a first direction, wherein the first direction is perpendicular to the upper surface of the package substrate, wherein the upper surface of the package substrate includes a first region and a second region that extends around the first region, and wherein the lower surface of the package substrate includes a third region and a fourth region that extends around the third region; external connection pads in the fourth region on the lower surface of the package substrate; a plurality of first sensing patterns in the first region, extending in a second direction, being spaced apart from each other in a third direction; a plurality of second sensing patterns in the first region, wherein the plurality of second sensing patterns are spaced apart from the plurality of first sensing patterns in the first direction, and wherein the plurality of second sensing patterns extend in the third direction and spaced apart from each other in the second direction; a control portion in the third region, the control portion including a sensor chip and a passive element adjacent the sensor chip; a lower protection layer on the lower surface of the package substrate and having openings that overlap at least a portion of the external connection pads in the first direction respectively, and the lower protection layer including a protection layer pattern that overlaps the external connection pads in the first direction in the openings; and an anisotropic conductive layer on the external connection pads in the openings and on the lower protection layer, wherein the second direction and the third direction are parallel with the upper surface of the package substrate, and wherein the second direction and the third direction intersect with each other.

In accordance with example embodiments, a fingerprint sensor package may include a lower protection layer covering the lower surface of the package substrate and having a protection pattern having openings exposing the external connection pads respectively, and covering at least a portion of the exposed external connection pads in each of the openings and an anisotropic conductive layer covering the exposed external connection pads in each of the openings and covering the lower protection layer in a form of a band shape.

The openings and the external connection pads may have a certain step to provide an accommodation space therein. Accordingly, when performing the compression process for mounting the fingerprint sensor package on a smart card, the conductive balls in the anisotropic conductive film may be trapped in the accommodation space without escaping the fingerprint sensor package.

Thus, short circuits in the fingerprint sensor package due to the escape of the anisotropic conductive film can be prevented, and more conductive balls come into contact with the external connection pad compared to the prior art, thereby increasing electrical conductivity and improving the stability of bonding.

### BRIEF DESCRIPTION OF THE DRAWINGS

Example embodiments of the present inventive concepts will be more clearly understood from the following detailed description taken in conjunction with the accompanying drawings. FIGS. 1 to 21 represent non-limiting, example embodiments as described herein.

FIGS. 1 to 9 are views illustrating a fingerprint sensor package in accordance with example embodiments.

FIGS. 10 to 18 are views illustrating a method for manufacturing a smart card in accordance with example embodiments.

FIGS. 19 to 21 are views illustrating a fingerprint sensor package in accordance with example embodiments.

### DETAILED DESCRIPTION OF THE INVENTION

Hereinafter, example embodiments of the present inventive concepts will be explained in detail with reference to the accompanying drawings.

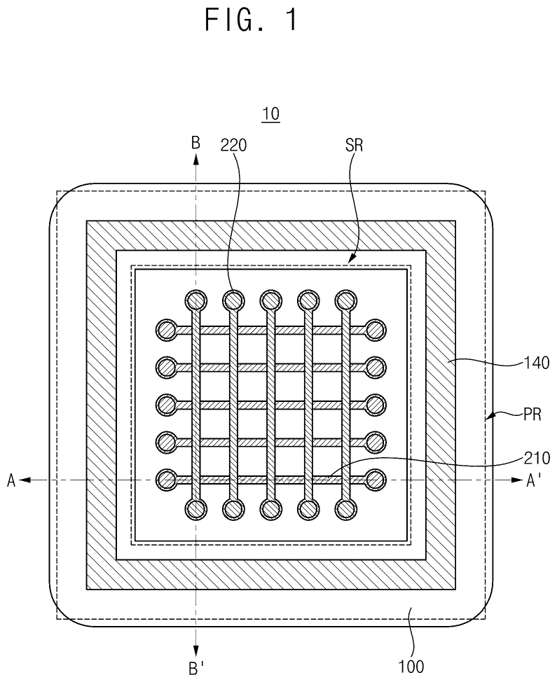

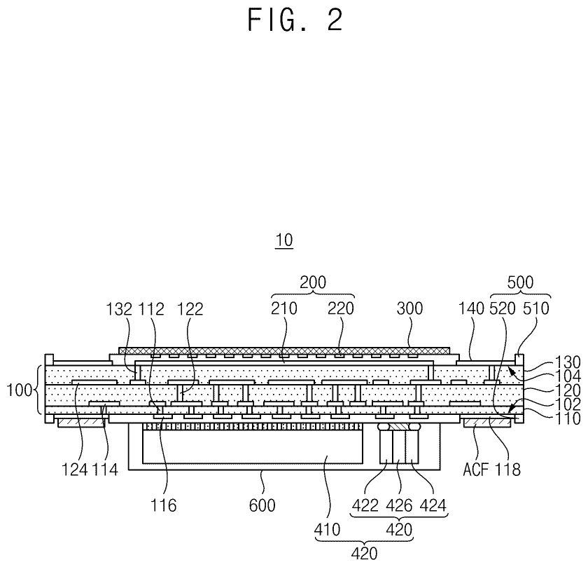

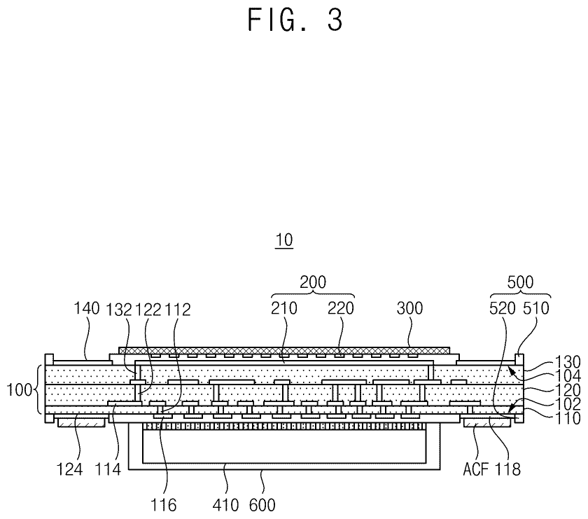

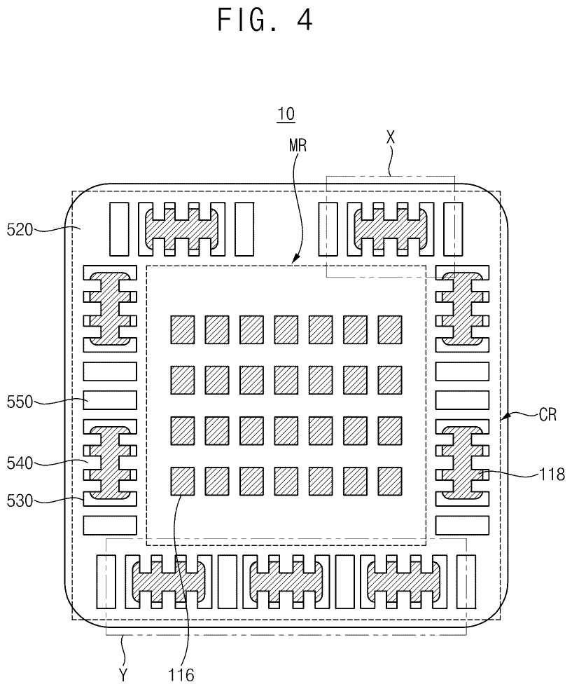

FIG. 1 is a plan view illustrating a fingerprint sensor package in accordance with example embodiments. FIG. 2 is a cross-sectional view taken along the line A-A′ in FIG. 1. FIG. 3 is a cross-sectional view taken along the line B-B′ in FIG. 1. FIG. 4 is a bottom view illustrating a package substrate of the fingerprint sensor package of FIG. 1.

Referring to FIGS. 1 to 4, a fingerprint sensor package 10 may include a package substrate 100, a sensing portion 200 provided on the package substrate 100, a coating member 300 on (e.g., overlapping or covering) the sensing portion 200, a control portion 400 including a sensor chip 410 that is configured to process information obtained from the sensing portion 200, a protection layer 500, a molding member 600 on (e.g., overlapping or covering) the control portion 400, and an anisotropic conductive film ACF on (e.g., overlapping or covering) a lower protection layer 520 (in a band shape in a plan view). The anisotropic conductive film ACF may be referred to as an anisotropic conductive layer ACF. In some embodiments, the coating member 300 may overlap (e.g., cover) the sensing portion 200 (in a third direction). The molding member 600 may overlap (e.g., cover) the control portion 400 (in a first direction, a second direction, and/or the third direction). The anisotropic conductive layer ACF may overlap (e.g., cover) the lower protection layer 520 (in the first direction, the second direction, and/or the third direction). As used herein, “an element A overlapping an element B in a direction X” (or similar language) means that there is at least one line that extends in the direction X and intersects both the elements A and B. The first direction and the second direction may be parallel with an upper surface 104 and/or a lower surface 102 of the package substrate 100. The first direction and the second direction may intersect with (may be perpendicular to) each other. The third direction may be perpendicular to the upper surface 104 and/or the lower surface 102 of the package substrate 100.

In example embodiments, when a user contacts the sensing portion 200 (the fingerprint sensor), the fingerprint sensor package 10 may recognize a fingerprint of the user. The fingerprint sensor package 10 may compare the information on the fingerprint with a pre-stored fingerprint information to verify the identity of the user. When the user contacts the sensing portion 200, different deformation occurs in portions (e.g., each portion) of the sensing portion 200 (the fingerprint sensor) due to the irregularities of the fingerprint. The fingerprint sensor package 10 may include a capacitive fingerprint sensor that determines the shape of the fingerprint by calculating the value of the deformation based on a value difference in capacitance recognized by the sensor. For example, the sensing portion 200 may be the capacitive fingerprint sensor.

As illustrated in FIGS. 2 and 3, the package substrate 100 may include a printed circuit board (PCB). The package substrate 100 may be a printed circuit board including redistribution wirings of a multi-layered structure. The package substrate 100 may have, for example, a shape of a rectangular plane or a square plane (in a plan view). In some embodiments, the package substrate 100 may have a shape in which each corner is rounded (in a plan view), and thus, cracks may be effectively prevented from occurring at the corners in the process of cutting the package substrate 100 through a punching process. However, the shape of the package substrate 100 is not limited to the above-noted shapes.

The package substrate 100 may include first, second, and third insulating layers 110, 120, and 130 sequentially stacked, a plurality of first and second redistribution wirings 114 and 124 provided in the first, second, and third insulating layers 110, 120, and 130, a plurality of first, second, and third through vias 112, 122, and 132, electrode pads 116, and external connection pads 118.

The package substrate 100 may further include a conductive external connection member on a lower surface 102 of the package substrate 100. In accordance with a type of the conductive external connection member, the package substrate 100 may include a ball grid array (BGA) or a land grid array (LGA).

The first, second, and third insulating layers 110, 120, and 130 may include a polymer, a dielectric layer, etc. For example, the first, second, and third insulating layers 110, 120, and 130 may include a photosensitive insulating layer such as a photo imageable dielectric (PID). The first, second, and third insulating layers 110, 120, and 130 may be formed by a vapor deposition process, a spin coating process, etc. The first and second redistribution wirings 114 and 124 and the first, second, and third through vias 112, 122, and 132 may include, for example, aluminum (Al), copper (Cu), tin (Sn), nickel (Ni), gold (Au), platinum (Pt), and/or an alloy thereof. The first and second redistribution wirings 114 and 124 may be formed by a plating process, an electroless plating process, a vapor deposition process, etc.

As illustrated in FIG. 4, a lower surface of the first insulating layer 110, that may be, the lower surface 102 of the package substrate 100 may include a mounting region MR and a connection region CR extending around (e.g., surrounding) the mounting region MR (in the plan view). The electrode pads 116 may be provided in the mounting region MR on the lower surface of the first insulating layer 110. The electrode pads 116 may be arranged in an array form in the mounting region MR. The sensor chip 410 and passive elements 420 may be on the lower surface of the first insulating layer 110 in the mounting region MR (mounted in the mounting region MR). The electrode pads 116 may electrically connect the sensor chip 410, the passive elements 420, and the package substrate 100. It will be understood that when an element or layer is referred to as being “on”, “connected to”, “coupled to”, or “responsive to” another element or layer, it may be directly on, directly connected to, directly coupled to, or directly responsive to the other element or layer, or one or more intervening elements or layers may be present. In contrast, when an element is referred to as being “directly on”, “directly connected to”, “directly couple to,” or “directly responsive to”, another element, there are no intervening elements present. In addition, “electrical connection” conceptually includes a physical connection and a physical disconnection.

The external connection pads 118 may be provided on the lower surface of the first insulating layer 110 in the connection region CR. The external connection pads 118 may electrically connect the fingerprint sensor package 10 to a (payment) device (e.g., a smart card) when the fingerprint sensor package 10 is mounted on the (payment) device (e.g., the smart card). The external connection pads 118 may have, for example, a rectangular shape with a long side, a short side and rounded corners (in a plan view). In some embodiments, a length of the long side may be within a range of (about) 2.4 mm to (about) 2.8 mm. A length of the short side may be within a range of (about) 1.3 mm to (about) 1.7 mm. The shape and size of the external connection pads 118 are not limited to above-noted descriptions. The external connection pads 118 may be disposed to be spaced apart from each other along the periphery of the mounting region MR. For example, the external connection pads 118 may be spaced apart from each other in the first direction and/or the second direction.

The first through vias 112 may be provided in the first insulating layer 110. The first through vias 112 may extend in (e.g., penetrate) the first insulating layer 110 (in the third direction). In some embodiments, the first through vias 112 may extend from the lower surface of the first insulating layer 110 to an upper surface opposite to the lower surface of the first insulating layer 110 (in the third direction). The first through vias 112 may be electrically connected to the electrode pads 116 in the mounting region MR and the external connection pads 118 in the connection region CR.

The first redistribution wirings 114 may be provided on the first insulating layer 110. The first redistribution wirings 114 may be electrically connected to the electrode pads 116 and the external connection pads 118 through the first through vias 112 in the first insulating layer 110.

The second insulating layer 120 may be provided on the first insulating layer 110. The second through vias 122 may be provided in the second insulating layer 120. The second through vias 122 may extend in (e.g., penetrate) the second insulating layer 120 (in the third direction). In some embodiments, the second through vias 122 may extend from a lower surface of the second insulating layer 120 to an upper surface of the second insulating layer 120 opposite to the lower surface (in the third direction). In some embodiments, the second through vias 122 may be (electrically) connected to the first redistribution wirings 114 provided on the first insulating layer 110.

The second redistribution wirings 124 may be provided on the second insulating layer 120. The second redistribution wirings 124 may be connected (e.g., electrically connected) to the first redistribution wirings 114 through second through vias 122 in the second insulating layer 120.

The third insulating layer 130 may be provided on the second insulating layer 120. The third through vias 132 may be provided in the third insulating layer 130. The third through vias 132 may extend in (e.g., penetrate) the third insulating layer 130 (in the third direction). In some embodiments, the third through vias 132 may extend from a lower surface of the third insulating layer 130 to an upper surface of the third insulating layer 130 opposite to the lower surface (in the third direction). In some embodiments, the third through vias 132 may be (electrically) connected to the second redistribution wirings 124 provided on the second insulating layer 120.

The upper surface of the third insulating layer 130, that may be, the upper surface 104 of the package substrate 100 may include a sensing region SR and a peripheral region PR extending around (e.g., surrounding) the sensing region SR (in a plan view). The sensing region SR may be a region in which the sensing portion 200 including a first sensing pattern 210 and a second sensing pattern 220 for fingerprint recognition is disposed. The sensing region SR may be located in a central region of the third insulating layer 130 (in a plan view), but is not limited thereto. The sensing region SR may have a rectangular shape in a plan view, but is not limited thereto.

A ground pattern 140 may be provided in the peripheral region PR on the upper surface of the third insulating layer 130. The ground pattern 140 may provide a reference potential (e.g., reference electric potential or reference electrostatic potential) to the sensor chip 410 and may serve to shield noise when the sensing portion 200 senses a user's fingerprint. The ground pattern 140 may have an annular shape to extend around (e.g., surround) the sensing region SR (in a plan view). For example, the ground pattern 140 may be disposed horizontally along the periphery of the sensing region SR and may be formed in a closed annular pattern having a predetermined width. For example, the sensing region SR may be between portions of the ground pattern 140 in a cross-sectional view. The ground pattern 140 may be electrically connected to the sensor chip 410 through the first, second, and third through vias 112, 122, and 132 and the first and second redistribution wirings 114 and 124.

The sensing portion 200 may include a plurality of first sensing patterns 210 and a plurality of second sensing patterns 220 as a plurality of capacitor patterns. The first sensing patterns 210 may be provided on the upper surface of the third insulating layer 130. In some embodiments, each of the first sensing patterns 210 may have a linear shape extending in the first direction on the upper surface of the third insulating layer 130. The first sensing patterns 210 may be disposed to be spaced apart from each other at regular intervals in the second direction. At least one end of both ends of the first sensing patterns 210 extending in the first direction may be (electrically) connected to the third through vias 132, and each of the neighboring first sensing patterns 210 may be electrically separated (e.g., insulated) from each other.

The second sensing patterns 220 may be provided to be spaced apart from the first sensing patterns 210 on the upper surface of the third insulating layer 130 in the third direction. Each of the second sensing patterns 220 may have a linear shape extending in the second direction. The second sensing patterns 220 may be disposed to be spaced apart from each other in the first direction. At least one end of both ends of the second sensing patterns 220 extending in the second direction may be (electrically) connected to the third through vias 132, and each of the neighboring second sensing patterns 220 may be electrically separated (e.g., insulated) from each other.

As illustrated in FIG. 1, when viewed in a plan view, the first sensing patterns 210 and the second sensing patterns 220 may be arranged to have a plurality of crossing points to constitute a plurality of sensing pixels. The sensing pixels may be arranged in the first direction and the second direction. That is, the sensing pixels may be arranged in an array form. Since the first sensing patterns 210 and the second sensing patterns 220 are spaced apart in the third direction, the sensing pixels may have capacitance values. A value of capacitance corresponding to each of the sensing pixels may be changed by the capacitance induced by the unevenness of the user's fingerprint. Accordingly, the user's fingerprint information may be recognized by the sensing pixels to identify the user's fingerprint. In the capacitance value, sensing noise may occur in accordance with the shape of the user's fingerprint and the surrounding environment (e.g., the external environment). Accordingly, (in a plan view) the ground pattern 140 may be provided to extend around (e.g., surround) the sensing region SR in order to minimize the sensing noise. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The coating member 300 may be on (e.g., overlap with in the third direction or cover) the sensing portion 200 including the first sensing patterns 210 and the second sensing patterns 220 in the sensing region SR on the upper surface 104 of the package substrate 100. The coating member 300 may protect the sensing portion 200 from contamination or damage caused by an external impact on the sensing region SR. The coating member 300 may be provided to directly contact a fingerprint of a user. The coating member 300 may include a material having a dielectric constant suitable for fingerprint recognition. The coating member 300 may protrude from (the upper surface 104 of) the package substrate 100 in the third direction and may be formed to have a thickness of (about) 50 μm or less in the third direction in consideration of sensing sensitivity. For example, the thickness of the coating member 300 may be within a range of (about) 5 μm to (about) 50 μm.

The control portion 400 may include the sensor chip 410 and the passive element 420. The control portion 400 may be disposed in the mounting region MR on the lower surface of the first insulating layer 110, that may be, the lower surface 102 of the package substrate 100.

The sensor chip 410 may be configured to perform an operation for recognizing a user's fingerprint based on changes in capacitance values of the sensing pixels. For example, the sensor chip 410 may include a memory chip and/or a processor chip. The passive element 420 may include a capacitor that stores capacitance induced by the first sensing pattern 210 and the second sensing pattern 220. The sensor chip 410 may be mounted on the package substrate 100 through the electrode pads 116 provided on the lower surface of the first insulating layer 110. The sensor chip 410 may be electrically connected to the first sensing pattern 210 and the second sensing pattern 220 through the plurality of first and second redistribution wirings 114 and 124 and the plurality of first, second, and third through vias 112, 122, and 132.

The passive element 420 may include a first conductive terminal 422, a second conductive terminal 424, and an insulator 426. The first conductive terminal 422 and the second conductive terminal 424 may be a first electrode and a second electrode, respectively. The insulator 426 may be provided between the first conductive terminal 422 and the second conductive terminal 424. A plurality of passive elements 420 may be provided adjacent to the sensor chip 410. Each of the passive elements 420 may be disposed in parallel to be spaced apart from each other. The passive elements 420 may be mounted on the package substrate 100 through the electrode pads 116 provided on the lower surface of the first insulating layer 110.

The protection layer 500 may include an upper protection layer 510 and a lower protection layer 520. The upper protection layer 510 may be on (e.g., overlap in the third direction or cover) the upper surface 104 of the package substrate 100. The upper protection layer 510 may be provided on the third insulation layer 130 to expose (at least a portion of) the ground pattern 140.

The lower protection layer 520 may be on (e.g., overlap in the third direction or cover) the lower surface 102 of the package substrate 100. The lower protection layer 520 may include openings 530 that expose (at least a portion of) the external connection pads 118 provided on the lower surface 102 of the package substrate 100, respectively. Herein, an opening exposing an element A may refer to an opening disposed in an overlapping position with the element A (in the third direction). Each of the openings 530 may have a shape corresponding to a shape of each of the external connection pads 118. For example, each of the openings 530 may have a size greater than a size of each of the external connection pads 118 (in a plan view) in order to expose (at least a portion of) the external connection pads 118. For example, when each of the external connection pads 118 has a rectangular shape with rounded corners, each of the openings 530 may have a long side and a short side and may be provided to have a rectangular shape greater than the rectangular shape of the external connection pads 118 in a plan view to expose (at least a portion of) the external connection pads 118, respectively. A length of the long side of the opening 530 may be within a range of (about) 2.8 mm to (about) 3.2 mm. A length of the short side of the opening 530 may be within a range of (about) 1.7 mm to (about) 2.1 mm. The shapes and sizes of the external connection pads 118 and the openings 530 are not limited to the above-noted descriptions.

The lower protection layer 520 may expose the electrode pads 116 in the mounting region MR. Since the electrode pads 116 are arranged in an array form in the mounting region MR on the lower surface 102 of the package substrate 100, the lower protection layer 520 may have openings for exposing electrode pads 116 arranged in an array form similarly to expose the electrode pads 116. Accordingly, the sensor chip 410 and the passive elements 420 may be electrically connected to the electrode pads 116, such that the sensor chip 410 and the passive elements 420 may be electrically connected to the sensing portion 200 including the first sensing patterns 210 and the second sensing patterns 220, that may be, a plurality of capacitor patterns (e.g., sensing pixels), to receive information.

As illustrated in FIG. 4, the anisotropic conductive layer ACF may be on (e.g., overlap in the third direction or cover) the lower protection layer 520 on the lower surface 102 of the package substrate 100. The anisotropic conductive layer ACF may have, for example, a band shape (in a plan view), that may be, an annular shape (in the plan view). The anisotropic conductive layer ACF may be provided in the connection region CR extending around (e.g., surrounding) the mounting region MR (in a plan view) on the lower surface 102 of the package substrate 100. The anisotropic conductive layer ACF may be disposed to overlap in the third direction (e.g., cover) the openings 530 and accommodation grooves 550 on the lower protection layer 520.

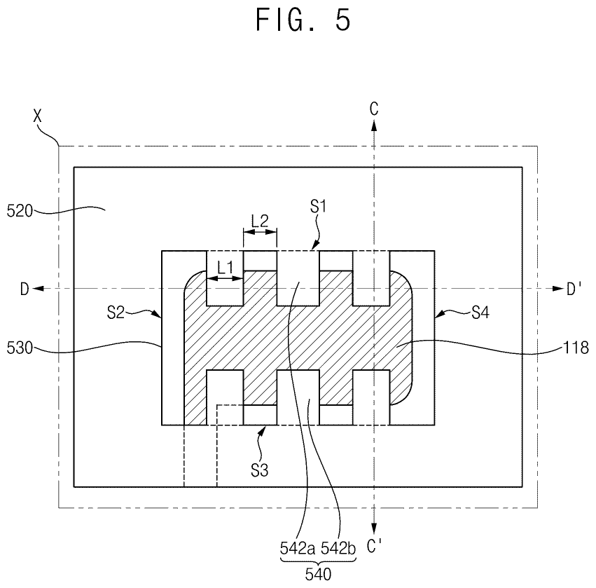

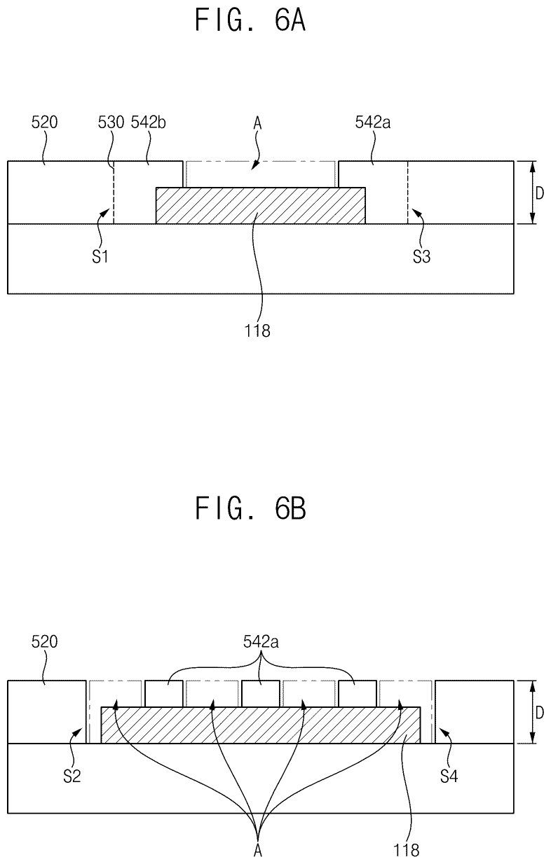

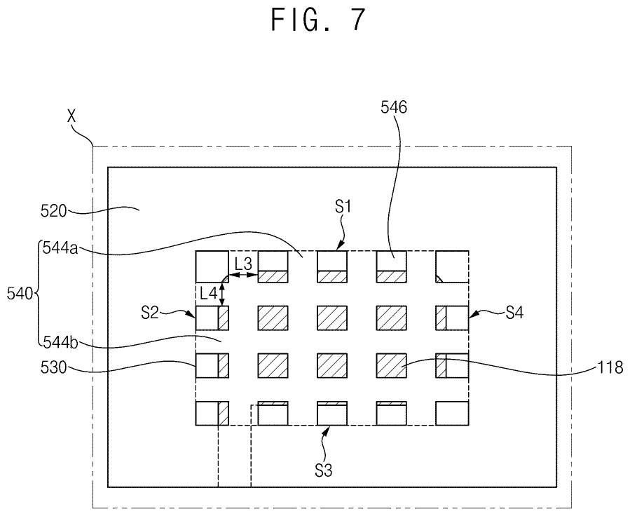

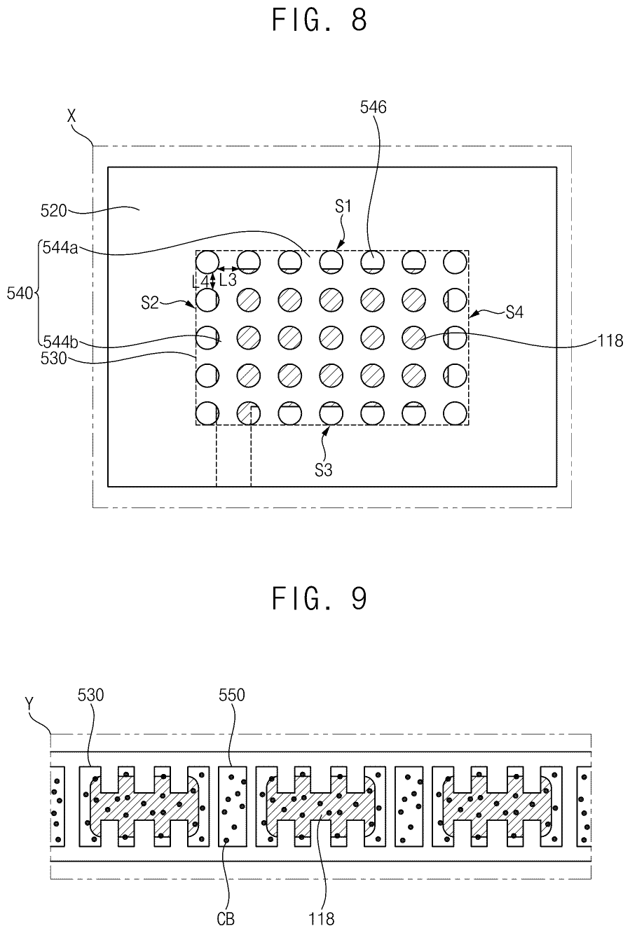

FIGS. 5 to 8 are enlarged views of the portion ‘X’ in FIG. 4. FIG. 5 is a plan view illustrating a protection layer pattern 540. FIG. 6A is a cross-sectional view of the protection layer pattern 540 taken along the line C-C′ in FIG. 5. FIG. 6B is a cross-sectional view of the protection layer pattern 540 taken along the line D-D′ in FIG. 5. FIGS. 7 and 8 illustrate plan views of the protection layer pattern 540 according to some embodiments.

Referring to FIGS. 5 to 8, the lower protection layer 520 may further include a protection layer pattern 540 that overlaps at least a portion of the external connection pads 118 in the opening 530, when viewed in a plan view. For example, the protection layer pattern 540 may overlap with the external connection pads 118 in the third direction. The protection layer pattern 540 may include a material corresponding to that of the lower protection layer 520. For example, the lower protection layer 520 and the protection layer pattern 540 may have the same material. In some embodiments, the protection layer pattern 540 may be a portion of the lower protection layer 5320.

As illustrated in FIG. 5, the protection layer pattern 540 may include first protrusion portions 542a and second protrusion portions 542b. The first protrusion portions 542a may extend from a first side portion S1 of the opening 530 in a direction perpendicular to the extending direction of the first side portion S1 (e.g., in the second direction). The second protrusion portions 542b may extend from a third side portion S3 opposite to the first side portion S1 of the opening 530 in a direction perpendicular to the extending direction of the third side portion S3 (e.g., in the second direction). In some embodiments, the first protrusion portions 542a may obliquely extend with a preset angle with respect to the extending direction of the first side portion S1 of the opening 530. The second protrusion portions 542b may obliquely extend with a preset angle with respect to the extending direction of the third side portion S3 of the opening 530. Herein, a side portion (e.g., the first side portion S1) of the opening 530 may refer to a corresponding side surface of the lower protection layer 520 exposed by the opening 530.

The first protrusion portions 542a may be spaced apart from each other along the first side portion S1 of the opening 530. The second protrusion portions 542b may be spaced apart from each other along the third side portion S3 of the opening 530. For example, as illustrated in FIG. 5, three first protrusion portions 542a and three second protrusion portions 542b may be arranged along the first side portion S1 and the third side portion S3 of the opening 530, respectively. Each of the first and second protrusion portions 542a and 542b may have a width L1 (in the first direction). Adjacent ones of the first protrusion portions 542a may be spaced apart from each other by a spacing distance L2 (in the first direction). Adjacent ones of the second protrusion portions 542b may be spaced apart from each other by the spacing distance L2 (in the first direction). The width L1 may be at least 80 μm. The spacing distance L2 between the protrusion portions may be at least 100 μm.

As illustrated in FIGS. 6A and 6B, the openings 530 may have a step portion H of a predetermined height with respect to the external connection pads 118. The height of the step portion H may be a distance from an upper surface of the external connection pads 118 in the third direction. The height of the step portion H may be within a range of (about) 15 μm to (about) 25 μm. Accordingly, the openings 530 may provide an accommodation space A therein. In order to position (e.g., mount) the fingerprint sensor package 10 on a (payment) device (e.g., a smart card), when the anisotropic conductive layer ACF as a conductive connection member is positioned on the external connection pads 118 and then compressed, the anisotropic conductive layer ACF may be confined in the accommodation space A without escaping the connection region CR.

As illustrated in FIGS. 7 and 8, the protection layer pattern 540 may include first extension portions 544a and second extension portions 544b. The first extension portions 544a may be provided to extend between (from) the first side portion S1 of the opening 530 and (to) the third side portion S3 facing the first side portion S1 (in the second direction). A plurality of first extension portions 544a may be disposed in parallel to be spaced apart from each other along the first side portion S1 of the opening 530. For example, the first extension portions 544a may be spaced apart from each other in the first direction. The second extension portions 544b may be provided to extend between (from) a second side portion S2 perpendicular to the first side portion S1 of the opening 530 and (to) a fourth side portion S4 facing the second side portion S2 (in the first direction). A plurality of second extension portions 544b may be disposed in parallel to be spaced apart from each other along the second side portion S2 of the opening 530. For example, the second extension portions 544b may be spaced apart from each other in the second direction. The first extension portions 544a may have a width L3 in the extending direction of the first side portion S1 of the opening 530. For example, each of the first extension portions 544a may have a width L3 in the first direction. The second extension portions 544b may have a width L4 in the extending direction of the second side portion S2 of the opening 530. For example, each of the second extension portions 544b may have a width L4 in the second direction. A width (e.g., the width L3) of the first extension portion 544a in the extending direction of the first side portion S1 (e.g., the first direction) and a width (e.g., the width L4) of the second extension portion 544b in the extending direction of the second side portion S2 (e.g., the second direction) may be at least 80 μm, respectively. In some embodiments, the first extension portions 544a and the second extension portions 544b may form an integrated unitary structure. An integrated unitary structure herein may refer to a structure without a visible boundary between sub-elements (e.g., the first extension portions 544a and the second extension portions 544b) thereof.

The first extension portions 544a and the second extension portions 544b may extend in a direction perpendicular to each other to define a plurality of accommodation cavities 546 that expose the external connection pads 118. Each of the accommodation cavities 546 may have a rectangular or circular shape in a plan view, but not limited thereto. In some embodiments, the width L3 of the first extension portion 544a may be a distance (e.g., the closest distance) between adjacent accommodation cavities 546 arranged in the first direction. The width L4 of the second extension portion 544b may be a distance (e.g., the closest distance) between adjacent accommodation cavities 546 arranged in the second direction. The accommodation cavities 546 may be arranged in an array form. The accommodation cavities 546 may provide an accommodation space A therein. In order to position (e.g., mount) the fingerprint sensor package 10 on a (payment) device (e.g., a smart card), when the anisotropic conductive layer ACF as a conductive connection member is positioned on the external connection pads 118 and then pressed, the anisotropic conductive layer ACF may be confined in the accommodation space A without escaping the connection region CR.

When the anisotropic conductive layer ACF is placed on the external connection pads 118 and then compressed to mount the fingerprint sensor package 10 on a (payment) device (e.g., a smart card), the protection layer pattern 540 may allow conductive balls CB in the anisotropic conductive layer ACF to be positioned (accommodated) between the protective layer patterns 540 (in the accommodation space of the plurality of accommodation cavities 546), thereby preventing the conductive ball CB from escaping the connection area CR. When viewed in a plan view, the protection layer pattern 540 may (partially) overlap the external connection pad 118 (in the third direction). An area of a portion where the protection layer pattern 540 overlaps the external connection pad 118 may be (about) 20% or less of an area of the external connection pad 118 (in a plan view). Accordingly, an area for stably and electrically connected between the external connection pad 118 and a substrate pad (e.g., the substrate pad 830 to be described later) of the (payment) device (e.g., the smart card) may be secured.

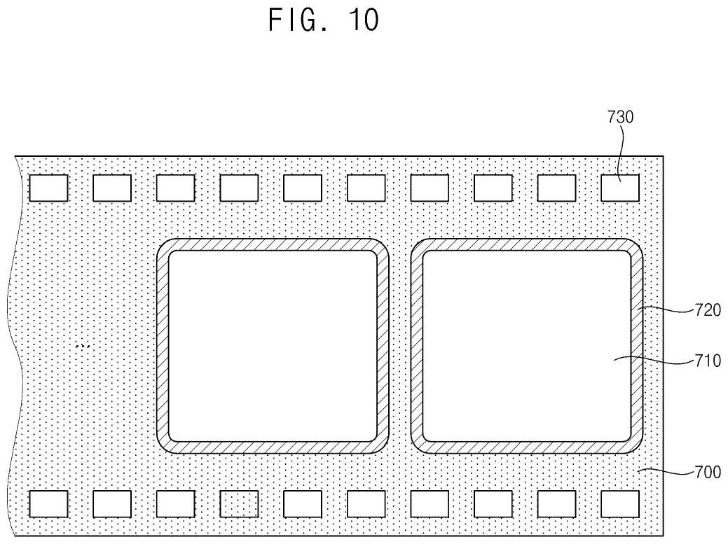

FIG. 9 is an enlarged plan view (e.g., bottom view) illustrating portion ‘Y’ in FIG. 4 when the anisotropic conductive layer ACF is compressed. The lower protection layer 520 may further include an accommodation groove 550 in a region other than a region in which the openings 530 in the connection region CR are located. Like the openings 530, the accommodation groove 550 may have a step difference and may provide an accommodation space (corresponding to the accommodation space A of the openings 530) therein. The accommodation groove 550 may be positioned between the openings 530. The accommodation groove 550 may have a rectangular shape but is not limited thereto. The accommodation groove 550 may trap conductive balls CB in the accommodation space of the accommodation groove 550 so as to prevent the conductive balls CB in the anisotropic conductive layer ACF from escaping the openings 530 and/or the accommodation groove 550 when the anisotropic conductive layer ACF is compressed.

In example embodiments, the molding member 600 may be provided to be on (e.g., overlap or cover) the control portion 400 including the sensor chip 410 and the passive elements 420 in the mounting region MR on the lower surface 102 of the package substrate 100. The molding member 600 may serve to protect the sensor chip 410 and the passive elements 420 from external influences such as contamination, impact, and the like. The molding member 600 may include, for example, an epoxy mold compound (EMC). The molding member 600 may include, for example, a UV resin, a polyurethane resin, a silicon resin, a silica filler, and the like.

The conductive balls CB in the anisotropic conductive layer ACF may be trapped in the openings 530 without escaping the fingerprint sensor package 10 when performing a compression process for mounting the fingerprint sensor package 10 on a (payment) device (e.g., a smart card).

Thus, short circuits in the fingerprint sensor package 10 due to the escape of the anisotropic conductive layer ACF may be reduced (e.g., prevented), and the conductive balls CB come into contact with the external connection pad 118, thereby increasing electrical conductivity and improving the stability of bonding between the fingerprint sensor package 10 and a (payment) device (e.g., a smart card).

Hereinafter, a method of manufacturing a (payment) device (e.g., a smart card) in accordance with example embodiments will be described.

FIGS. 10 to 18 are views illustrating a method of manufacturing a smart card in accordance with embodiments.

Referring to FIG. 10, a base layer 700 on which a fingerprint sensor package 10 will be positioned (e.g., mounted) may be prepared. The base layer 700 may include an open region 710, an adhesion region 720 extending around (e.g., surrounding) the open region 710 (in a plan view), and a plurality of holes 730 disposed in opposite sides of the open region 710 (in the first direction or in the second direction). For example, in a plan view, the open region 710 may be between a first group of holes among the plurality of holes 730 and a second group of holes among the plurality of holes 730 in the second direction. The fingerprint sensor packages 10 may be disposed in the open regions 710 of the base layer 700, respectively. A width and a length of the base layer 700 may be determined in accordance with the number and size of the fingerprint sensor packages 10 to be positioned (e.g., mounted) thereon. The base layer 700 may be provided in the form of a reel in which the plurality of holes 730 are configured to be wound or unwound through a winding reel mechanism.

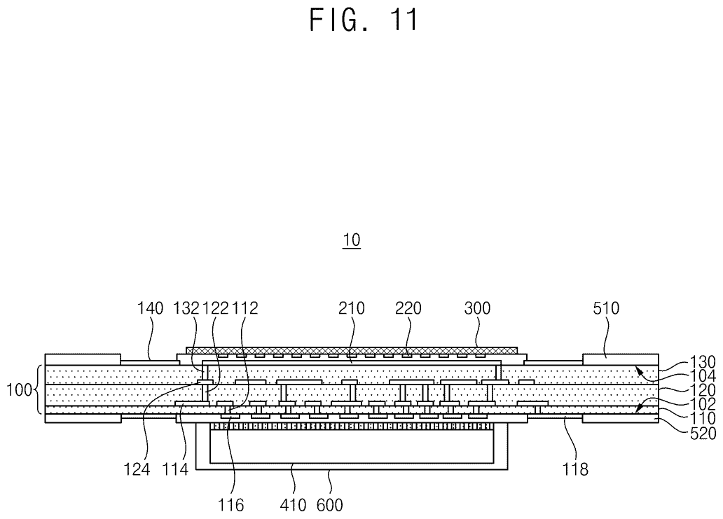

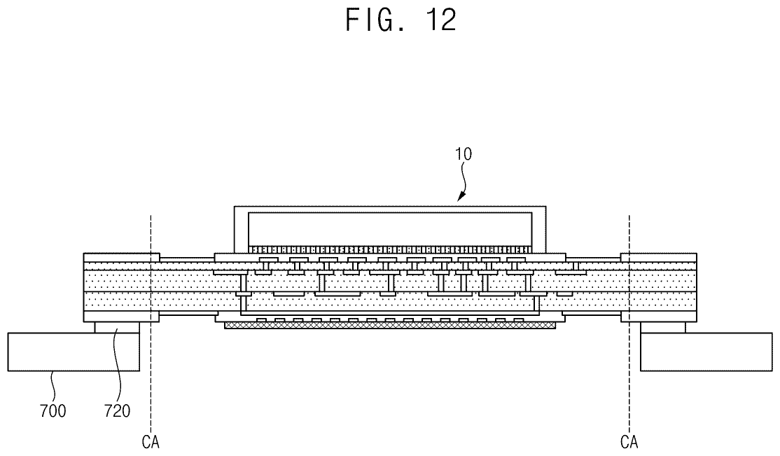

Referring to FIGS. 11 and 12, the fingerprint sensor package 10 may be aligned and disposed on the base layer 700. A lower protection layer 520 of a package substrate 100 of the fingerprint sensor package 10 may be adhered to the adhesion region 720 of the base layer 700. Then, the package substrate 100 may be cut along the cutting region using a punching apparatus to separate an individual fingerprint sensor package 10 from the base layer 700. The fingerprint sensor package 10 may have a shape in which each corner is rounded. Therefore, it may be possible to effectively reduce (e.g., prevent) cracks from occurring in the corners in the process of cutting the package substrate 100 through a punching process.

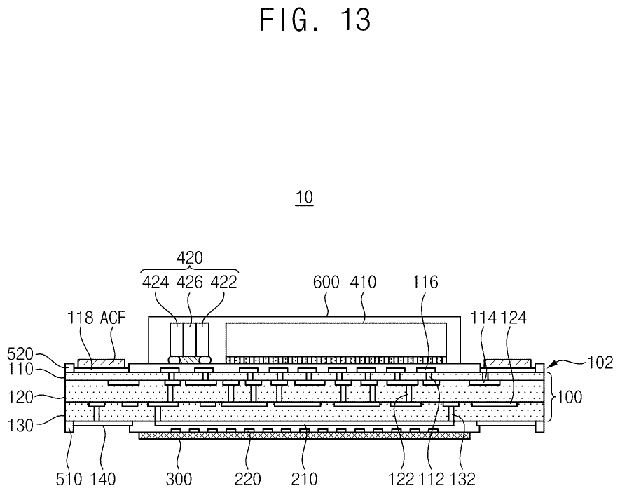

Then, referring to FIG. 13, an anisotropic conductive layer ACF may be on (e.g., may overlap with in the third direction or cover) the external connection pad 118. In some embodiments, the anisotropic conductive layer ACF may be on the lower protection layer 520 on the lower surface 102 of the package substrate 100. For example, the anisotropic conductive layer ACF may overlap with (e.g., cover) the lower protection layer 520 (in the first direction, the second direction, and/or the third direction). The lower surface 102 of the package substrate 100 in FIG. 13 is illustrated to face upward as the fingerprint sensor package 10 is flipped in FIG. 13.

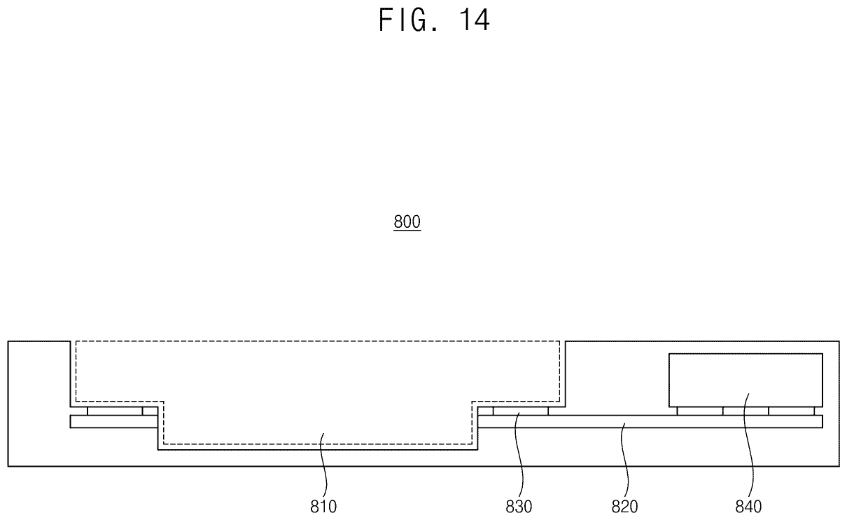

Referring to FIG. 14, a smart card 800 including a groove region 810, a card substrate 820, a substrate pad 830, and a security chip 840 may be prepared. The card substrate 820 and the security chip 840 for storing financial information may be disposed in the smart card 800. The groove region 810 may provide a space for positioning (e.g., mounting) the fingerprint sensor package 10. The substrate pad 830 may be provided in the groove region 810 to electrically connect the fingerprint sensor package 10, the card substrate 820, and the security chip 840.

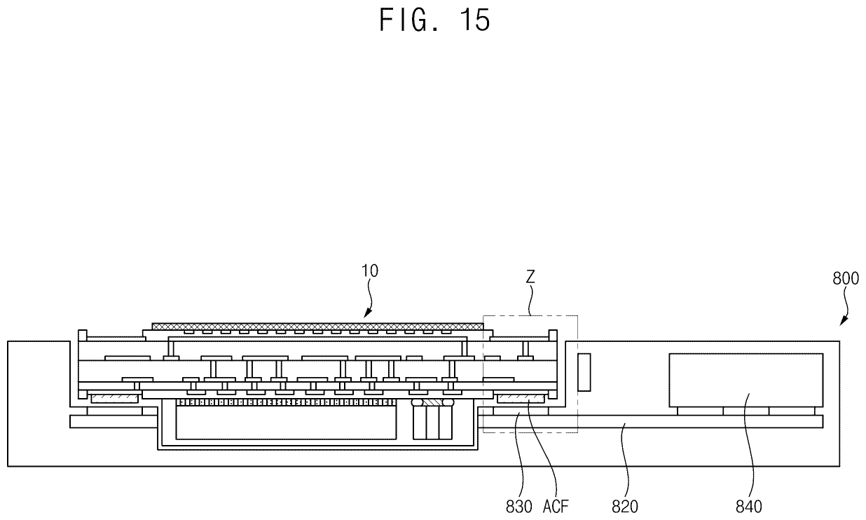

Referring to FIG. 15, the fingerprint sensor package 10 may be positioned (e.g., mounted) in the groove region 810. External connection pads 118 on the lower surface 102 of the package substrate 100 of the fingerprint sensor package 10 may be electrically connected to the substrate pad 830 of the smart card 800. The anisotropic conductive layer ACF may be provided between the external connection pads 118 and the substrate pad 830. The anisotropic conductive layer ACF may include a plurality of conductive balls CB therein. When the fingerprint sensor package 10 is pressed to be positioned (e.g., mounted) on the smart card 800, the external connection pads 118 of the fingerprint sensor package 10 may be electrically connected to the substrate pad 830 of the smart card 800 through the plurality of conductive balls CB.

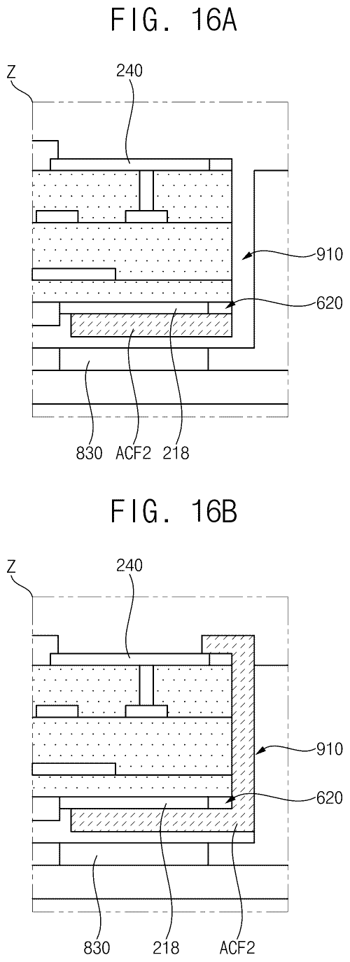

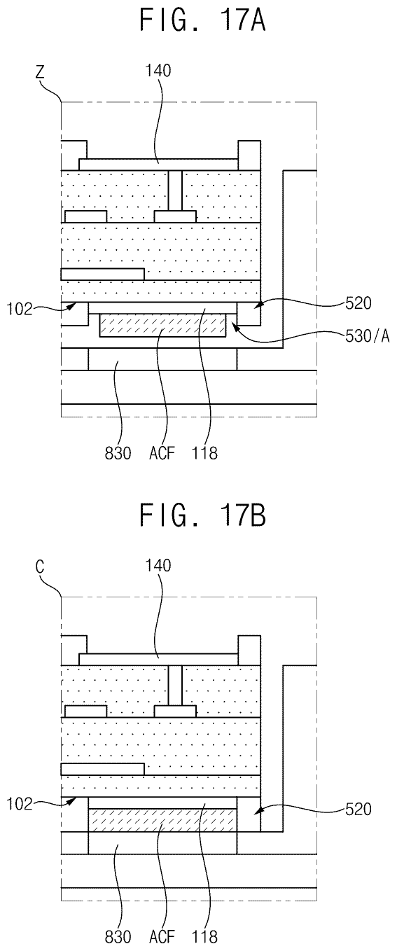

FIGS. 16A and 16B are enlarged views illustrating portion ‘Z’ in FIG. 15. FIGS. 16A and 16B are views showing an anisotropic conductive layer ACF2 (corresponding to the anisotropic conductive layer ACF) when a fingerprint sensor package according to a related art is mounted. Referring to FIG. 16A, a fingerprint sensor package according to the related art does not have a step difference between an external connection pads 218 (corresponding to the external connection pads 118) and a lower protection layer 620 (corresponding to the lower protection layer 520). Thus, referring to FIG. 16B, when the fingerprint sensor package is compressed, an anisotropic conductive layer ACF 2 may escape through a space between the fingerprint sensor package and the groove region 910 (corresponding to the groove region 810) of a smart card by vertical pressure to be in contact with a ground pattern 240 (corresponding to the ground pattern 140) of the fingerprint sensor package, thereby causing an electrical short. FIGS. 17A and 17B are views illustrating an anisotropic conductive layer ACF when a fingerprint sensor package 10 in accordance with example embodiments is mounted on the (payment) device (e.g., the smart card 800). Referring to FIG. 17A, the openings 530 on the lower protection layer 520 of the fingerprint sensor package 10 may have a step difference from that of the external connection pad 118. Similarly, a plurality of accommodation grooves 550 have a step difference on the protection layer 500 to provide an accommodation space therein. The anisotropic conductive layer ACF may be guided by the accommodation grooves 550 and/or the openings 530 of the protection layer pattern 540 such that the conductive balls CB are accommodated therein. Thus, as illustrated in FIG. 17B, the anisotropic conductive layer ACF may remain in the accommodation space A provided between the substrate pad 830 of the smart card 800 and the connection region CR on the lower surface 102 of the package substrate 100 of the fingerprint sensor package 10. Compared to a fingerprint sensor package according to the related art in FIGS. 16A and 16B, more conductive balls CB may stay between the external connection pad 118 and the substrate pad 830, thereby increasing electrical conductivity and thus the fingerprint sensor package 10 may be stably bonded.

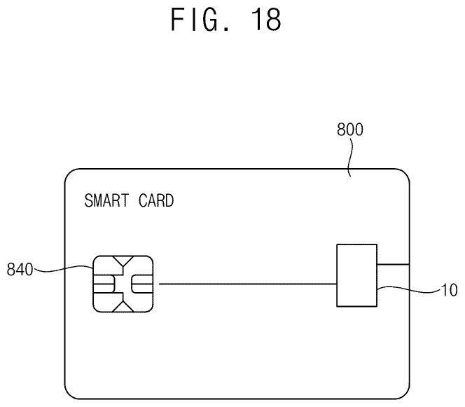

Referring to FIG. 18, a smart card 800 may include the fingerprint sensor package 10 and the security chip 840. The fingerprint of the user may be recognized by contacting the fingerprint sensor package 10 of the smart card 800 with the fingerprint. When the recognized and registered fingerprints match, the security chip 840 may grant the user payment authority.

Hereinafter, a fingerprint sensor package (corresponding to the fingerprint sensor package 10) in accordance with example embodiments of the present inventive concepts and a smart card including the fingerprint sensor package will be described.

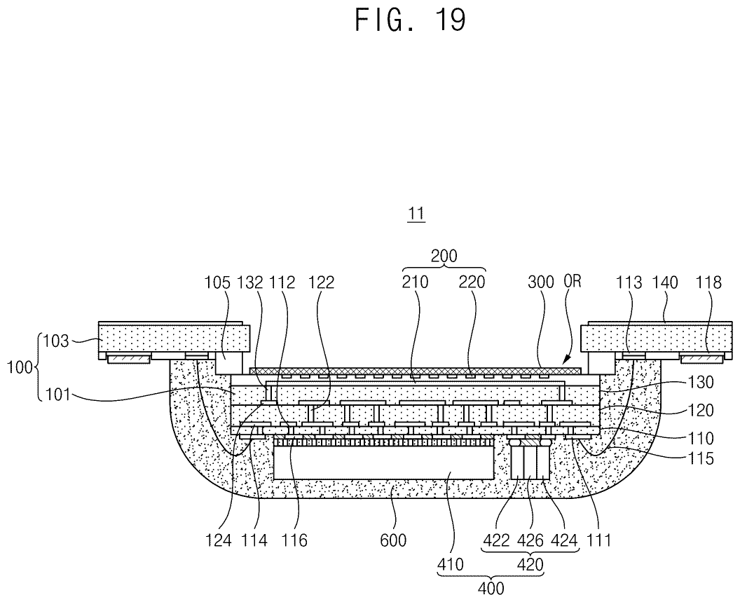

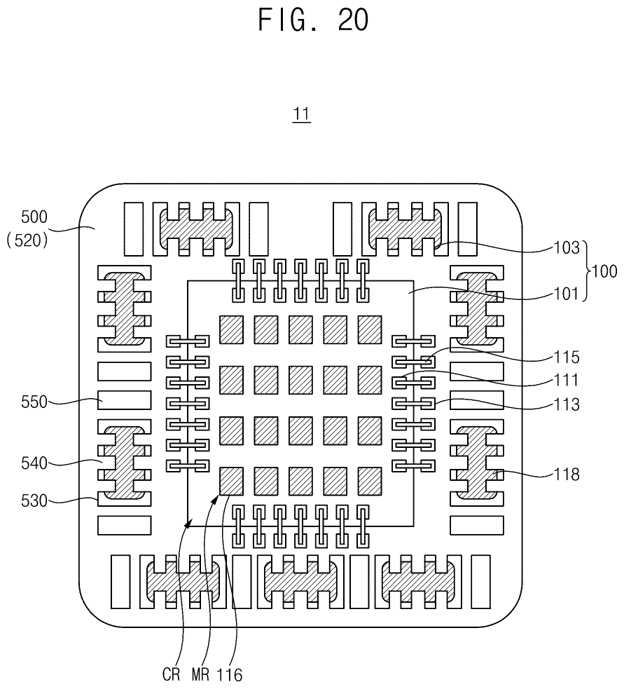

FIGS. 19 to 21 are views illustrating a fingerprint sensor package in accordance with example embodiments of the present inventive concepts. FIG. 19 is a cross-sectional view illustrating a fingerprint sensor package 11 in accordance with example embodiments. FIG. 20 is a bottom view illustrating the fingerprint sensor package 11 of FIG. 19. Components constituting the fingerprint sensor package 11 described below are substantially the same as or similar to those of the fingerprint sensor package 10 described in FIGS. 1 to 7, and thus differences will be mainly described.

Referring to FIGS. 19 and 20, the fingerprint sensor package 11 may include a first substrate 101, a second substrate 103, a sensing portion 200 provided on the first substrate 101, a coating member 300 on (e.g., overlapping in the third direction or covering) the sensing portion 200, a control portion 400 configured to process information obtained from the sensing portion 200, a protection layer 500, and a molding member 600 on (e.g., overlapping or covering) the control portion 400.

The first substrate 101 may include a plurality of first, second, and third insulating layers 110, 120, and 130, a plurality of first and second redistribution wirings 114 and 124 provided in the first, second, and third insulating layers 110, 120, and 130, a plurality of first, second, and third through vias 112, 122, and 132, electrode pads 116, and first bonding pads 111. The first substrate 101 may have a rectangular or square shape in a plan view but is not limited thereto.

An upper surface of the first substrate 101, that is, an upper surface of the third insulating layer 130 may include a sensing region SR and a substrate adhesion region extending around (e.g., surrounding) the sensing region SR in a plan view. The sensing region SR may be a region in which the sensing portion 200 including a first sensing pattern 210 and a second sensing pattern 220 for fingerprint recognition is disposed. The sensing region SR may be positioned in a central region of the third insulating layer 130, but is not limited thereto. The sensing region SR may have a square shape in a plan view. The substrate adhesion region may be a region in which an adhesive layer 105 for bonding the first substrate 101 to the second substrate 103 is disposed. The adhesive layer 105 may be disposed (in a band shape in a plan view) on the substrate adhesion region extending around (e.g., surrounding) the sensing region SR in a plan view.

A lower surface 102 of the first substrate 101, that is, a lower surface of the first insulating layer 110 may include a mounting region MR and a connection region CR extending around (e.g., surrounding) the mounting region MR. The mounting region MR may be a region in which the control portion 400 including a sensor chip 410 and passive elements 420 is located. The connection region CR may be a region in which the first bonding pads 111 for electrically connecting the first substrate 101 to the second substrate 103 are located. The first bonding pads 111 may be disposed on the first insulating layer 110 to be spaced apart from each other along the periphery of the mounting region MR.

The second substrate 103 may have an upper surface and a lower surface opposite to the upper surface in the third direction. The second substrate 103 may include an open region OR having a shape corresponding to the shape of the first substrate 101 so as to expose the upper surface of the coating member 300. The lower surface of the second substrate 103 may include an adhesion region 720, which overlaps at least a portion of the first substrate 101 when viewed in a plan view. Accordingly, the second substrate 103 may be fixedly connected to the first substrate 101 through the adhesive layer 105 disposed in the adhesion region 720.

The second substrate 103 may include a ground pattern 140 on an upper surface thereof. The ground pattern 140 may have a band shape extending around (e.g., surrounding) the open region OR. The ground pattern 140 may be configured to provide a reference potential to the sensor chip 410 and may be configured to serve to shield noise when the sensing portion 200 senses a user's fingerprint.

As illustrated in FIG. 20, second bonding pads 113 may be provided on the lower surface of the second substrate 103 along an inner circumference (of the second substrate 103) adjacent (close to) the first substrate 101. The second bonding pads 113 may be electrically connected to the first bonding pads 111 of the first substrate 101 using conductive wires 115. External connection pads 118 may be provided on the lower surface of the second substrate 103 along an outer circumference far from the first substrate 101 (e.g., farther from the first substrate 101 than the second bonding pads 113). For example, in a cross-sectional view, the external connection pads 118 may be disposed farther from the second bonding pads 113 in the first direction and/or the second direction. The external connection pads 118 may be electrically connected to substrate pads 830 when the fingerprint sensor package 11 is mounted on the smart card 800.

A lower protection layer 520 may be provided on the lower surface of the second substrate 103. The lower protection layer 520 may cover the lower surface of the second substrate 103 to expose (at least a portion of) the second bonding pads 113. The lower protection layer 520 may include openings 530 that expose (at least a portion of) the external connection pads 118. The openings 530 have a step difference from the external connection pads 118 and may provide an accommodation space A therein. In embodiments, the lower protection layer 520 may further include a protection layer pattern 540 and an accommodation groove 550.

The molding member 600 may be provided to be on (e.g., overlap or cover) the control portion 400 including the sensor chip 410 and the passive elements 420 on the lower surface 102 of the first substrate 101, the first bonding pads 111, the second bonding pads 113 on the lower surface of the second substrate 103, and the conductive wires 115 (electrically) connecting the first bonding pads 111 to the second bonding pads 113. The molding member 600 may include, for example, an epoxy mold compound (EMC). The molding member 600 may include, for example, a UV resin, a polyurethane resin, a silicon resin, a silica filler, etc.

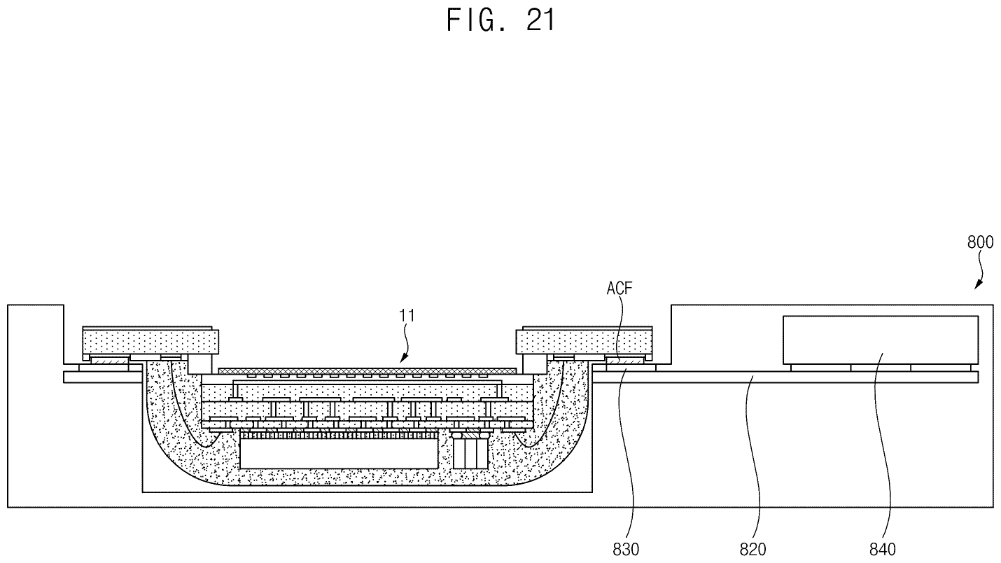

Referring to FIG. 21, a smart card 800 including a groove region 810, a card substrate 820, a substrate pad 830, and a security chip 840 may be prepared. The fingerprint sensor package 11 may be mounted in the groove region 810. The external connection pads 118 on the lower surface of the second substrate 103 of the fingerprint sensor package 11 may be electrically connected to the substrate pads 830 of the smart card 800. An anisotropic conductive layer ACF may be provided between the external connection pads 118 and the substrate pads 830. The anisotropic conductive layer ACF may include a plurality of conductive balls CB therein. When the fingerprint sensor package 11 is compressed to be mounted on the smart card 800, the external connection pads 118 of the fingerprint sensor package 11 may be electrically connected to the substrate pad 830 of the smart card 800 through the plurality of conductive balls CB.

The foregoing is illustrative of example embodiments and is not to be construed as limiting thereof. Although a few example embodiments have been described, those skilled in the art will readily appreciate that various modifications are possible in some example embodiments without materially departing from the scope, novel teachings, and advantages of the present invention. Accordingly, all such modifications are intended to be included within the scope of example embodiments as defined in the claims.

What is claimed is:

1. A fingerprint sensor package, comprising:
a package substrate including an upper surface and a lower surface that is opposite to the upper surface in a first direction,
wherein the first direction is perpendicular to the upper surface of the package substrate,
wherein the upper surface of the package substrate includes a sensing region and a peripheral region that extends around the sensing region, and
wherein the lower surface of the package substrate includes a mounting region and a connection region that extends around the mounting region;
external connection pads in the connection region on the lower surface of the package substrate;
a plurality of capacitor patterns in the sensing region on the upper surface of the package substrate;
a control portion in the mounting region on the lower surface of the package substrate,
wherein the control portion includes a sensor chip and a passive element that is adjacent the sensor chip;
a lower protection layer on the lower surface of the package substrate,
wherein the lower protection layer includes openings that overlap at least a portion of the external connection pads in the first direction respectively,
wherein the lower protection layer includes a protection layer pattern that overlaps the external connection pads in the first direction in the openings; and
an anisotropic conductive layer on the external connection pads in the openings and on the lower protection layer.

2. The fingerprint sensor package of claim 1, wherein the protection layer pattern comprises:
a plurality of first extension portions extending between a first side portion and a third side portion of each of the openings, wherein the third side portion faces the first side portion in a second direction; and
a plurality of second extension portions extending between a second side portion and a fourth side portion of each of the openings, wherein the fourth side portion faces the second side portion in a third direction,
wherein the first extension portions and the second extension portions intersect each other to provide a plurality of accommodation cavities that overlap at least a portion of the external connection pads in the first direction,
wherein the second direction and the third direction are parallel with the upper surface of the package substrate, and
wherein the second direction and the third direction intersect with each other.

3. The fingerprint sensor package of claim 2, wherein each of the accommodation cavities has a rectangular or circular shape in a plan view.

4. The fingerprint sensor package of claim 1, wherein the protection layer pattern comprises:
a plurality of first protrusion portions protruding from a first side portion of each of the openings to extend in a second direction; and
a plurality of second protrusion portions protruding from a second side portion of each of the openings to extend in the second direction,
wherein the second side portion faces the first side portion in the second direction,
wherein the first side portion and the second side portion extend in a third direction,
wherein the first protrusion portions are spaced apart from each other in the third direction,
wherein the second protrusion portions are spaced apart from each other in the third direction,
wherein the second direction and the third direction are parallel with the upper surface of the package substrate, and
wherein the second direction and the third direction are perpendicular to each other.

5. The fingerprint sensor package of claim 1, wherein an area of a portion of the external connection pads that is overlapped by the protection layer pattern is less than 20% of an area of the external connection pads.

6. The fingerprint sensor package of claim 1, wherein the openings have a step difference from the external connection pads in the first direction to have an accommodation space, and the step difference is within a range of 15 μm to 25 μm.

7. The fingerprint sensor package of claim 1, wherein the lower protection layer further comprises accommodation grooves between the openings, each of the accommodation grooves having an accommodation space therein.

8. The fingerprint sensor package of claim 7, wherein each of the accommodation grooves has a rectangular or circular shape in a plan view.

9. The fingerprint sensor package of claim 1, further comprising:
a molding member on the sensor chip and the passive element.

10. A fingerprint sensor package, comprising:
a package substrate including:
a first substrate having a sensing region and an adhesion region extending around the sensing region on an upper surface thereof and having first bonding pads on a lower surface thereof; and
a second substrate having second bonding pads and external connection pads on a lower surface thereof, the second bonding pads being electrically connected to the first bonding pads through conductive wires, the second substrate having an opening region that overlaps the sensing region of the upper surface of the first substrate in a first direction, the second substrate being adhered on the adhesion region of the upper surface of the first substrate;
a plurality of capacitor patterns in the sensing region on the upper surface of the first substrate;
a control portion on the lower surface of the first substrate, the control portion including a sensor chip and a passive element adjacent the sensor chip;
a lower protection layer on the lower surface of the second substrate and having openings that overlap the external connection pads in the first direction respectively, the lower protection layer having a protection layer pattern that overlaps a portion of the external connection pads in the openings in the first direction; and
an anisotropic conductive layer on the external connection pads in the openings and on the lower protection layer,
wherein the first direction is perpendicular to the upper surface of the first substrate.

11. The fingerprint sensor package of claim 10, wherein the protection layer pattern comprises:
a plurality of first extension portions extending between a first side portion and a third side portion of each of the openings, wherein the third side portion faces the first side portion in a second direction; and
a plurality of second extension portions between from a second side portion and a fourth side portion of each of the openings, wherein the fourth side portion faces the second side portion in a third direction,
wherein the first extension portions and the second extension portions intersect each other to provide a plurality of accommodation cavities that overlap at least a portion of the external connection pads in the first direction,
wherein the second direction and the third direction are parallel with the upper surface of the first substrate, and
wherein the second direction and the third direction intersect with each other.

12. The fingerprint sensor package of claim 11, wherein each of the accommodation cavities has a rectangular or circular shape in a plan view, and
wherein the anisotropic conductive layer is in a band shape in a plan view.

13. The fingerprint sensor package of claim 10, wherein the protection layer pattern comprises:
a plurality of first protrusion portions protruding from a first side portion of each of the openings to extend in a second direction; and
a plurality of second protrusion portions protruding from a second side portion of each of the openings to extend in the second direction,
wherein the second side portion faces the first side portion in the second direction,
wherein the first side portion and the second side portion extend in a third direction,
wherein the first protrusion portions are spaced apart from each other in the third direction,
wherein the second protrusion portions are spaced apart from each other in the third direction,
wherein the second direction and the third direction are parallel with the upper surface of the first substrate, and
wherein the second direction and the third direction are perpendicular to each other.

14. The fingerprint sensor package of claim 10, wherein an area of a portion of the external connection pads that is overlapped by the protection layer pattern is less than 20% of an area of the external connection pads.

15. The fingerprint sensor package of claim 10, wherein the openings have a step difference from the external connection pads in the first direction to have an accommodation space, and the step difference is within a range of 15 μm to 25 μm.

16. The fingerprint sensor package of claim 10, wherein the lower protection layer further comprises accommodation grooves between the openings, each of the accommodation grooves having an accommodation space therein.

17. The fingerprint sensor package of claim 16, wherein each of the accommodation grooves has a rectangular or circular shape in a plan view.

18. A fingerprint sensor package, comprising:
a package substrate including an upper surface and a lower surface that is opposite to the upper surface in a first direction,
wherein the first direction is perpendicular to the upper surface of the package substrate,
wherein the upper surface of the package substrate includes a first region and a second region that extends around the first region, and
wherein the lower surface of the package substrate includes a third region and a fourth region that extends around the third region;
external connection pads in the fourth region on the lower surface of the package substrate;
a plurality of first sensing patterns in the first region, extending in a second direction, being spaced apart from each other in a third direction;
a plurality of second sensing patterns in the first region, wherein the plurality of second sensing patterns are spaced apart from the plurality of first sensing patterns in the first direction, and wherein the plurality of second sensing patterns extend in the third direction and spaced apart from each other in the second direction;
a control portion in the third region, the control portion including a sensor chip and a passive element adjacent the sensor chip;
a lower protection layer on the lower surface of the package substrate and having openings that overlap at least a portion of the external connection pads in the first direction respectively, and the lower protection layer including a protection layer pattern that overlaps the external connection pads in the first direction in the openings; and
an anisotropic conductive layer on the external connection pads in the openings and on the lower protection layer,
wherein the second direction and the third direction are parallel with the upper surface of the package substrate, and
wherein the second direction and the third direction intersect with each other.

19. The fingerprint sensor package of claim 18, wherein the protection layer pattern comprises:
a plurality of first extension portions extending between a first side portion and a third side portion of each of the openings, wherein the third side portion faces the first side portion in the second direction; and
a plurality of second extension portions extending between a second side portion and a fourth side portion, wherein the fourth side portion faces the second side portion in the third direction, and
wherein the first extension portions and the second extension portions intersect each other to provide a plurality of accommodation cavities that overlap at least a portion of the external connection pads in the first direction.

20. The fingerprint sensor package of claim 18, wherein the protection layer pattern comprises:
a plurality of first protrusion portions protruding from a first side portion of each of the openings to extend in the second direction; and
a plurality of second protrusion portions protruding from a second side portion of each of the openings to extend in the second direction,
wherein the second side portion faces the first side portion in the second direction,
wherein the first side portion and the second side portion extend in the third direction,
wherein the first protrusion portions are spaced apart from each other in the third direction, and
wherein the second protrusion portions are spaced apart from each other in the third direction.
